(19) United States
(12) Patent Application Publication
(10) Pub. No.: US 2018/0032396 A1
(43) Pub. Date: Feb. 1, 2018

(54) GENERALIZED SYNDROME WEIGHTS

(71) Applicant: SANDISK TECHNOLOGIES LLC, PLANO, TX (US)

(72) Inventors: ERAN SHARON, RISHON LEZION (IL); STELLA ACHTENBERG, NETANYA (IL)

(73) Assignee: SANDISK TECHNOLOGIES LLC

(21) Appl. No.: 15/223,302

(22) Filed: Jul. 29, 2016

(51) Int. Cl. G06F 11/10; G11C 29/52; G06F 3/06; G11C 11/56

(52) U.S. Cl. CPC G06F 11/1072; G11C 11/5642; G11C 29/52; G06F 3/0619; G06F 3/064; G06F 3/0679

(57) ABSTRACT

A device includes a memory device and a controller. The controller is configured to determine, based on data read from the memory device, a first count of bits of the data that are associated with at least a first number of unsatisfied parity checks of the data and a second count of bits of the data that are associated with at least a second number of unsatisfied parity checks of the data. The controller is further configured to perform one or more operations based at least partially on the first count and the second count.

### FIELD OF THE DISCLOSURE

This disclosure is generally related to data storage devices and more particularly to data encoding and recovery.

### BACKGROUND

Non-volatile data storage devices, such as flash solid state drive (SSD) memory devices or removable storage cards, have allowed for increased portability of data and software applications. Flash memory devices can enhance data storage density by storing multiple bits in each flash memory cell. For example, Multi-Level Cell (MLC) flash memory devices provide increased storage density by storing 2 bits per cell, 3 bits per cell, 4 bits per cell, or more. Although increasing the number of bits per cell and reducing device feature dimensions may increase a storage density of a memory device, a bit error rate of data stored at the memory device may also increase.

Error correction coding (ECC) is often used to correct errors that occur in data read from a memory device. Prior to storage, data may be encoded by an ECC encoder to generate redundant information (e.g., “parity bits”) that are associated with parity check equations of the ECC encoding scheme and that may be stored with the data as an ECC codeword. As more parity bits are used, an error correction capacity of the ECC increases and a number of bits to store the encoded data also increases.

Data storage devices may use a bit error rate (BER) estimate associated with data read from the memory device for selecting or performing one or more operations. For example, memory management operations may use BER estimations to identify when a page of data is to undergo a read scrub or to verify that a data write operation has succeeded. BER estimation may be used for housekeeping operations, such as wear leveling, and for ECC decoding.

### BRIEF DESCRIPTION OF THE DRAWINGS

FIG. 1 is a block diagram of an illustrative example of a system including a data storage device configured to generate multiple counts of bits associated with different numbers of unsatisfied parity checks.

FIG. 2 is a diagram of a particular example of a simplified bipartite graph and a corresponding error metric that may be used by the data storage device of FIG. 1.

FIG. 3 is a flow diagram of a particular example of a method of operation that may be performed by the data storage device of FIG. 1.

FIG. 4A is a block diagram of an illustrative example of a non-volatile memory system including a controller that includes the bits-to-unsatisfied parity check counters of FIG. 1.

FIG. 4B is a block diagram of an illustrative example of a storage module that includes plural non-volatile memory systems that each may include the bits-to-unsatisfied parity check counters of FIG. 1.

FIG. 4C is a block diagram of an illustrative example of a hierarchical storage system that includes a plurality of storage controllers that each may include the bits-to-unsatisfied parity check counters of FIG. 1.

FIG. 5A is a block diagram illustrating an example of a non-volatile memory system including a controller that includes the bits-to-unsatisfied parity check counters of FIG. 1.

FIG. 5B is a block diagram illustrating exemplary components of a non-volatile memory die that may be coupled to a controller that includes the bits-to-unsatisfied parity check counters of FIG. 1.

### DETAILED DESCRIPTION

Particular examples in accordance with the disclosure are described below with reference to the drawings. In the description, common features are designated by common reference numbers. As used herein, “exemplary” may indicate an example, an implementation, and/or an aspect, and should not be construed as limiting or as indicating a preference or a preferred implementation. Further, it is to be appreciated that certain ordinal terms (e.g., “first” or “second”) may be provided for identification and ease of reference and do not necessarily imply physical characteristics or ordering. Therefore, as used herein, an ordinal term (e.g., “first,” “second,” “third,” etc.) used to modify an element, such as a structure, a component, an operation, etc., does not necessarily indicate priority or order of the element with respect to another element, but rather distinguishes the element from another element having a same name (but for use of the ordinal term). In addition, as used herein, indefinite articles (“a” and “an”) may indicate “one or more” rather than “one.” As used herein, a structure or operation that “comprises” or “includes” an element may include one or more other elements not explicitly recited. Further, an operation performed “based on” a condition or event may also be performed based on one or more other conditions or events not explicitly recited.

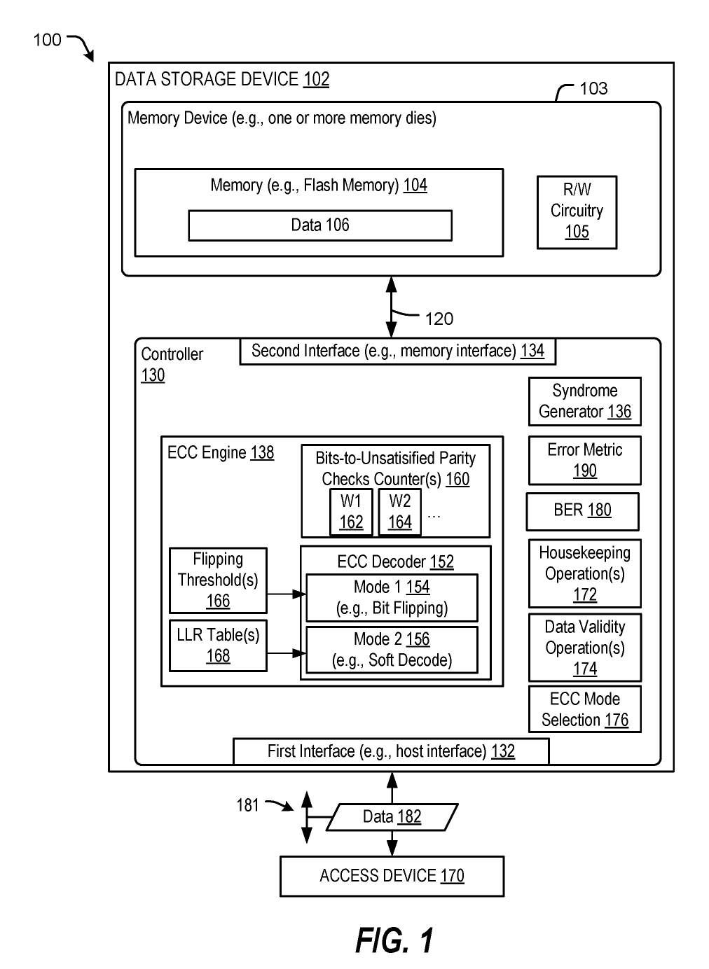

FIG. 1 depicts an illustrative example of a system 100 that includes a data storage device 102 and an access device 170 (e.g., a host device or another device). The data storage device 102 is configured to retrieve data from a memory 104 and to determine a first count of bits of the data that are associated with at least a first number of unsatisfied parity check equations and a second count of bits of the data that are associated with at least a second number of unsatisfied parity check equations, as described further herein.

The data storage device 102 and the access device 170 may be coupled via a connection (e.g., a communication path 181), such as a bus or a wireless connection. The data storage device 102 may include a first interface 132 (e.g., an access device or host interface) that enables communication via the communication path 181 between the data storage device 102 and the access device 170.

The data storage device 102 may include or correspond to a solid state drive (SSD) which may be included in, or distinct from (and accessible to), the access device 170. For example, the data storage device 102 may include or correspond to an SSD, which may be used as an embedded storage drive (e.g., a mobile embedded storage drive), an enterprise storage drive (ESD), a client storage device, or a cloud storage drive, as illustrative, non-limiting examples. In some implementations, the data storage device 102 is coupled to the access device 170 indirectly, e.g., via a network. For example, the network may include a data center storage system network, an enterprise storage system network, a storage area network, a cloud storage network, a local area network (LAN), a wide area network (WAN), the Internet, and/or another network. In some implementations, the data storage device 102 may be a network-attached storage (NAS) device or a component (e.g., a solid-state drive (SSD) device) of a data center storage system, an enterprise storage system, or a storage area network.

In some implementations, the data storage device 102 may be embedded within the access device 170, such as in accordance with a Joint Electron Devices Engineering Council (JEDEC) Solid State Technology Association Universal Flash Storage (UFS) configuration. For example, the data storage device 102 may be configured to be coupled to the access device 170 as embedded memory, such as eMMC® (trademark of JEDEC Solid State Technology Association, Arlington, Va.) and eSD, as illustrative examples. To illustrate, the data storage device 102 may correspond to an eMMC (embedded MultiMedia Card) device. As another example, the data storage device 102 may correspond to a memory card, such as a Secure Digital (SD®) card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). Alternatively, the data storage device 102 may be removable from the access device 170 (i.e., “removably” coupled to the access device 170). As an example, the data storage device 102 may be removably coupled to the access device 170 in accordance with a removable universal serial bus (USB) configuration.

The data storage device 102 may operate in compliance with an industry specification. For example, the data storage device 102 may include a SSD and may be configured to communicate with the access device 170 using a small computer system interface (SCSI)-type protocol, such as a serial attached SCSI (SAS) protocol. As other examples, the data storage device 102 may be configured to communicate with the access device 170 using a NVM Express (NVMe) protocol or a serial advanced technology attachment (SATA) protocol. In other examples, the data storage device 102 may operate in compliance with a JEDEC eMMC specification, a JEDEC Universal Flash Storage (UFS) specification, one or more other specifications, or a combination thereof, and may be configured to communicate using one or more protocols, such as an eMMC protocol, a universal flash storage (UFS) protocol, a universal serial bus (USB) protocol, and/or another protocol, as illustrative, non-limiting examples.

The access device 170 may include a memory interface (not shown) and may be configured to communicate with the data storage device 102 via the memory interface to read data from and write data to a memory device 103 of the data storage device 102. For example, the access device 170 may be configured to communicate with the data storage device 102 using a SAS, SATA, or NVMe protocol. As other examples, the access device 170 may operate in compliance with a Joint Electron Devices Engineering Council (JEDEC) industry specification, such as a Universal Flash Storage (UFS) Access Controller Interface specification. The access device 170 may communicate with the memory device 103 in accordance with any other suitable communication protocol.

The access device 170 may include a processor and a memory. The memory may be configured to store data and/or instructions that may be executable by the processor. The memory may be a single memory or may include multiple memories, such as one or more non-volatile memories, one or more volatile memories, or a combination thereof. The access device 170 may issue one or more commands to the data storage device 102, such as one or more requests to erase data, read data from, or write data to the memory device 103 of the data storage device 102. For example, the access device 170 may be configured to provide data, such as data 182, to be stored at the memory device 103 or to request data to be read from the memory device 103. The access device 170 may include a mobile telephone, a computer (e.g., a laptop, a tablet, or a notebook computer), a music player, a video player, a gaming device or console, an electronic book reader, a personal digital assistant (PDA), a portable navigation device, a computer, such as a laptop computer or notebook computer, a network computer, a server, any other electronic device, or any combination thereof, as illustrative, non-limiting examples.

The memory device 103 of the data storage device 102 may include one or more memory dies (e.g., one memory die, two memory dies, eight memory dies, or another number of memory dies). The memory device 103 includes a memory 104, such as a non-volatile memory of storage elements included in a memory die of the memory device 103. For example, the memory 104 may include a flash memory, such as a NAND flash memory, or a resistive memory, such as a resistive random access memory (ReRAM), as illustrative, non-limiting examples. In some implementations, the memory 104 may include or correspond to a memory die of the memory device 103. The memory 104 may have a three-dimensional (3D) memory configuration. As an example, the memory 104 may have a 3D vertical bit line (VBL) configuration. In a particular implementation, the memory 104 is a non-volatile memory having a 3D memory configuration that is monolithically formed in one or more physical levels of arrays of memory cells having an active area disposed above a silicon substrate. Alternatively, the memory 104 may have another configuration, such as a two-dimensional (2D) memory configuration or a non-monolithic 3D memory configuration (e.g., a stacked die 3D memory configuration).

Although the data storage device 102 is illustrated as including the memory device 103, in other implementations the data storage device 102 may include multiple memory devices that may be configured in a similar manner as described with respect to the memory device 103. For example, the data storage device 102 may include multiple memory devices, each memory device including one or more packages of memory dies, each package of memory dies including one or more memories such as the memory 104.

The memory 104 may include one or more blocks, such as a NAND flash erase group of storage elements. Each storage element of the memory 104 may be programmable to a state (e.g., a threshold voltage in a flash configuration or a resistive state in a resistive memory configuration) that indicates one or more values. Each block of the memory 104 may include one or more word lines. Each word line may include one or more pages, such as one or more physical pages. In some implementations, each page may be configured to store a codeword. A word line may be configurable to operate as a single-level-cell (SLC) word line, as a multi-level-cell (MLC) word line, or as a tri-level-cell (TLC) word line, as illustrative, non-limiting examples.

The memory device 103 may include support circuitry, such as read/write circuitry 105, to support operation of one or more memory dies of the memory device 103. Although depicted as a single component, the read/write circuitry 105 may be divided into separate components of the memory device 103, such as read circuitry and write circuitry. The read/write circuitry 105 may be external to the one or more dies of the memory device 103. Alternatively, one or more individual memory dies of the memory device 103 may include corresponding read/write circuitry that is operable to read data from and/or write data to storage elements within the individual memory die independent of any other read and/or write operations at any of the other memory dies.

The controller 130 is coupled to the memory device 103 via a bus 120, an interface (e.g., interface circuitry, such as a second interface 134), another structure, or a combination thereof. For example, the bus 120 may include one or more channels to enable the controller 130 to communicate with a single memory die of the memory device. As another example, the bus 120 may include multiple distinct channels to enable the controller 130 to communicate with each memory die of the memory device 103 in parallel with, and independently of, communication with other memory dies of the memory device 103.

The controller 130 is configured to receive data and instructions from the access device 170 and to send data to the access device 170. For example, the controller 130 may send data to the access device 170 via the first interface 132, and the controller 130 may receive data from the access device 170 via the first interface 132. The controller 130 is configured to send data and commands to the memory 104 and to receive data from the memory 104. For example, the controller 130 is configured to send data and a write command to cause the memory 104 to store data to a specified address of the memory 104. The write command may specify a physical address of a portion of the memory 104 (e.g., a physical address of a word line of the memory 104) that is to store the data. The controller 130 may also be configured to send data and commands to the memory 104 associated with background scanning operations, garbage collection operations, and/or wear leveling operations, etc., as illustrative, non-limiting examples. The controller 130 is configured to send a read command to the memory 104 to access data from a specified address of the memory 104. The read command may specify the physical address of a portion of the memory 104 (e.g., a physical address of a word line of the memory 104).

The controller 130 includes a syndrome generator 136 and an ECC engine 138. The syndrome generator 136 may include circuitry configured to perform one or more parity check operations on data 106 read from the memory 104. The syndrome generator 136 may be configured to generate a 1 bit for each parity check equation that is unsatisfied for the retrieved data 106 and a 0 bit for each parity check equation that is satisfied for the retrieved data 106. The resulting series of 1s and 0s corresponding to parity check equations may be referred to as the syndrome. The syndrome may be provided to the ECC engine 138 for further processing.

The ECC engine 138 is configured to receive data to be stored to the memory 104 and to generate a codeword. For example, the ECC engine 138 may include an encoder configured to encode data using an ECC scheme, such as a Reed Solomon encoder, a Bose-Chaudhuri-Hocquenghem (BCH) encoder, a low-density parity check (LDPC) encoder, a Turbo Code encoder, an encoder configured to encode one or more other ECC encoding schemes, or any combination thereof. The ECC engine 138 may include one or more decoders, such as a decoder 152, configured to decode data read from the memory 104 to detect and correct, up to an error correction capability of the ECC scheme, any bit errors that may be present in the data.

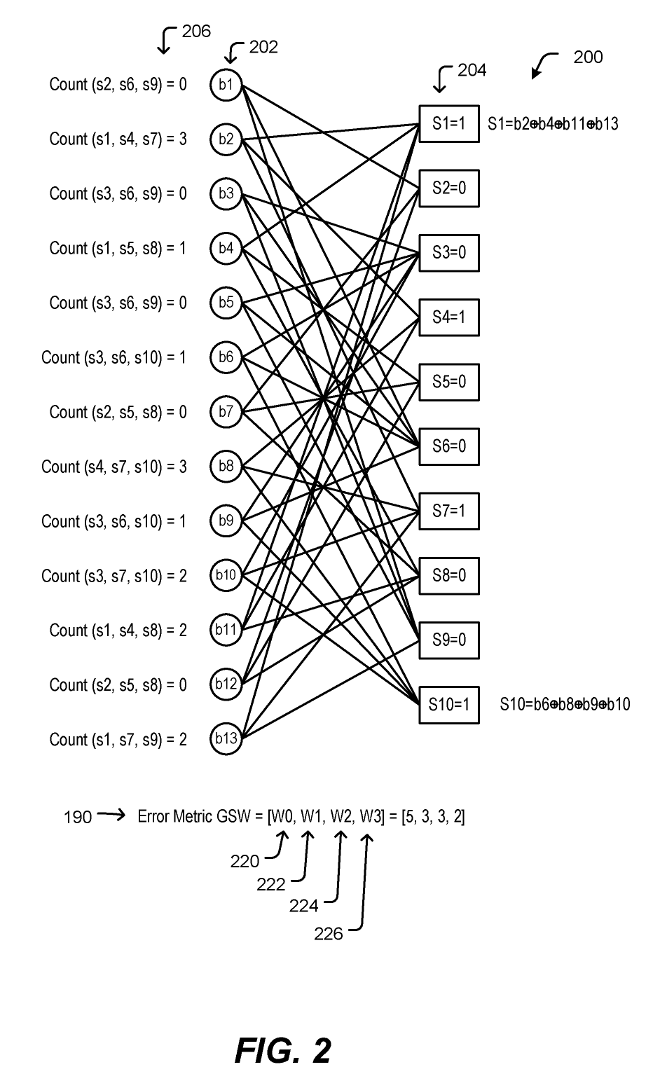

The ECC engine 138 includes multiple bits-to-unsatisfied parity checks counters 160. The counters 160 are configured to determine, for each bit of the received data 106, a count of unsatisfied parity check equations that bit participates in. For example, the counters 160 may include control circuitry configured to determine, for each bit of the data 106, how many 1 valued syndrome bits from the syndrome generator 136 are associated with that bit by accessing data corresponding to a bipartite graph of an ECC encoding scheme to determine which syndrome bits are associated with which of the bits of data 106. An example of a bipartite graph showing relationships between data bits to syndrome bits is described in further detail with respect to FIG. 2.

The counters 160 may configured to generate a first count W1 162 and a second count W2 164 for the data 106. The first count W1 162 may correspond to a count of the bits of data 106 that are associated with at least a first number of unsatisfied parity checks of the data 106. For example, when each bit of the data 106 may be associated with up to four parity checks, W1 162 may indicate a count of bits associated with one or two unsatisfied parity checks, and W2 164 may correspond to a second count of bits that are associated with three or four unsatisfied parity checks. As another example, the first count W1 162 may correspond to a count of bits associated with a single unsatisfied parity check. The second count W2 164 may correspond to a count of bits associated with two unsatisfied parity checks. In addition, a third count may correspond to bits associated with three unsatisfied parity checks, and a fourth count may correspond to bits associated with four unsatisfied parity check equations.

The controller 130 may be configured to use the counts 162-164 to perform one or more operations at the controller 130. For example, the ECC engine 138 may be configured to perform decoding in a first mode 154, such as a bit flipping mode, or in a second mode 156, such as a soft decode mode. The controller 130 may determine which mode of the ECC decoder 152 to initiate based on the first count 162 as compared to the second count 164. For example, data having a relatively large value of the first count 162 and a relatively small value of the second count 164 may correspond to data expected to be decodable using the bit flipping operation of the first mode 154. In contrast, data having relatively large levels of the first and second count 162-164 may be estimated to be undecodable using the first mode 154 and may be attempted to decode using the second mode 156.

As another example, when the first mode 154 is selected for decode processing of the data 106, the ECC decoder 152 may serially process each bit of the data 106 and may determine, for each bit, whether to change values of (“flip”) that bit based on a number of unsatisfied syndromes associated with that bit. For example, the ECC decoder 152 may compare the number of unsatisfied parity check equations for each bit to a flipping threshold 166 and may flip the bit in response to the number of unsatisfied parity check equations associated with the bit exceeding the flipping threshold 166. The controller 130 may be configured to adjust the flipping threshold 166 based on the first count 162 and the second count 164. For example, when the first count 162 is substantially greater than the second count 164, the flipping threshold 166 may be set to have a higher value, and when the first count 162 and the second count 164 have values more similar to each other, the flipping threshold 166 may be set to a lower value. A higher value of the flipping threshold 166 may indicate that bits are less likely to be flipped and therefore are considered more reliable, while a lower value of the flipping threshold 166 indicates that bits are considered less reliable.

As another example, when the first mode 154 is selected for decode processing of the data 106, the controller 130 may track a change of the first count 162 and the second count 164 based on one or more bit-flipping decisions. The controller 130 may “backtrack” or discard the one or more bit-flipping decisions based on the change of the first count 162 and the second count 164. For example, an error metric (e.g., an errors entropy) may be determined based on the first count 162 and the second count 164 during each iteration of the bit-flipping decoding operation, and a change in the error metric between successive iterations that indicates increased errors may cause the controller 130 to discard the changes of the most recent iteration. The controller 130 may select a more powerful decoding mode of the ECC decoder 152, may adjust one or more initial values or decoding parameters (e.g., reduce a bit-flipping threshold), or a combination thereof, and resume or re-attempt decoding of the data.

As another example, when the second mode 156 is selected for decode processing, one or more values of one or more log likelihood ratio (LLR) tables 168 may be adjusted at least partially based on the first count 162 and the second count 164. For example, the data 106 read from the memory device 103 may have read values, referred to as a hard bits, and reliability information, referred to as soft bits. The hard bits and soft bits may be provided to the LLR tables 168 and a corresponding LLR value for each bit of the data 106 may be provided as an initial data estimate to the ECC decoder 152. Translations between hard bits, soft bits, and LLR values may be adjusted based on the first count 162 and second count 164 to provide a more accurate initial estimate of the reliability of bits of the data 106 prior to decoding using the second mode 156.

As another example, the controller 130 may be configured to perform a particular number of ECC decoding iterations of an ECC decoding operation, such as when the second mode 156 is selected. The controller 130 may be configured to terminate the ECC decoding operation prior to completing the particular number of ECC decoding iterations. For example, early termination of the decoding operation may be triggered by all parity checks being satisfied (e.g., the first count 162 and the second count 164 are zero). Alternatively, early termination of the decoding operation may be triggered by a determination that an error condition of the data being decoded has failed to improve beyond a threshold amount between successive decoding iterations. For example, an error metric (e.g., an errors entropy) may be determined based on the first count 162 and the second count 164 during each iteration of the decoding operation, and a change in the error metric between successive iterations not satisfying the threshold amount may trigger early termination of the decoding operation. The controller 130 may select a more powerful decoding mode of the ECC decoder 152, may adjust one or more initial values or decoding parameters (e.g., reduced initial reliability), or a combination thereof, and re-attempt decoding of the data.

The controller 130 may be configured to generate an error metric 190. For example, the error metric 190 may include the first count 162 and second count 164 as elements of the error metric 190. For example, as illustrated in FIG. 2, the error metric 190 may include a generalized syndrome weight vector that includes multiple counts (e.g., counter values of the counters 160), such as by including a separate count for each possible number of unsatisfied parity check with which a bit may be associated. As an illustrative, non-limiting example, in a coding scheme in which each variable node may participate in up to three parity check equations (i.e., each bit is associated with up to three parity checks), the error metric 190 may have four values: a count of bits that are associated with zero unsatisfied parity check, a count of bits that are associated with one unsatisfied parity check, a count of bits that are associated with two unsatisfied parity checks, and a count of bits that are associated with three unsatisfied parity checks.

The controller 130 may further be able to perform one or more operations at least partially based on the first count 162 and the second count 164. To illustrate, the controller 130 may estimate a bit error rate (BER) 180 at least partially based on the first count 162 and the second count 164. The BER 180 generated using the first count 162 and the second count 164 may be more accurate than a BER estimate generated based solely on the syndrome weight (the total number of unsatisfied parity check equations) of the syndrome generated at the syndrome generator 136, as described in further detail with reference to FIG. 2.

The estimated BER 180 may be used to determine a validity of the data via one or more data validity operations 174. For example, the data validity operations 174 may include determining whether data was correctly written to the memory 104. For example, in the event of an unexpected power loss while a data write is ongoing at the memory 104, upon resumption of power, data in the process of being written may be corrupt and unrecoverable from the memory 104. The controller 130 may be configured to read such data upon resumption of power and to generate the estimated BER 180 based on the first count 162 and the second count 164. Validity of the data read from the memory 104 may be determined based on comparing the estimated BER 180 to a threshold. As another example, data may be read from the flash memory 104 and the BER 180 may be estimated based on the first count 162 and the second count 164 to verify that a data write or a data copy operation has succeeded without an unacceptable number of errors occurring within the data.

As another example, the controller 130 may be configured to perform one or more housekeeping operations 172 based on the first count 162 and the second count 164, such as by using the estimated BER 180. To illustrate, the housekeeping operations 172 may include a determination of a health metric for the memory 104, one or more decisions corresponding to wear leveling, such as active wear leveling management decisions, determinations about whether one or more pages of data the memory 104 is to be scrubbed, such as via a read scrub operation, one or more other operations, or a combination thereof.

As described above, the controller 130 may be configured to select an ECC decoding mode. Selection of the ECC decoding mode may be based on the estimated BER 180 (which is based on the counts 162-164). For example, the controller 130 may be configured to determine an ECC mode selection 176 based on the estimated BER 180.

By determining operations at the data storage device 102 based on the counts 162-164, the controller 130 may improve performance of the data storage device 102. For example, one or more decisions regarding the housekeeping operation(s) 172, the data validity operation(s) 174, the ECC mode selection 176, the flipping threshold(s) 166, the LLR table(s) 168, or any combination thereof, may be determined directly based on the counts 162-164, such as via one or more computations using one or more of the counts 162-164. Alternatively, or in addition, one or more of the decisions regarding the housekeeping operation(s) 172, the data validity operation(s) 174, the ECC mode selection 176, the flipping threshold(s) 166, the LLR table(s) 168, or any combination thereof, may be determined indirectly based on the counts 162-164, such as via computation of the estimated BER 180 using the counts 162-164, and comparison of the estimated BER 180 to one or more thresholds. Use of the counts 162-164, whether directly or indirectly via the estimated BER 180, provides a greater amount of information regarding bit errors as compared to using an alternative metric such as syndrome weight. As a result, decisions may be made with greater accuracy, resulting in improved performance of the data storage device 102.

Although the counters 160 are illustrated as including two counts 162-164, in other implementations the counters 160 may include three, four, or more counts. In addition, or alternatively, one or more of the counters 160 may represent bits associated with a single number of unsatisfied parity checks (e.g., one count of bits corresponding to zero unsatisfied parity check, another count of bits corresponding to one unsatisfied parity check, another count of bits corresponding to two unsatisfied parity checks, etc.), in other implementations one of more of the counters 160 may represent bits associated with multiple numbers of unsatisfied parity checks. For example, one count of bits may correspond to zero or one unsatisfied parity checks, another count of bits corresponding to two or three unsatisfied parity checks, etc. As another example, the counters may overlap count criteria. For example, one count of bits may correspond to bits associated with one, two, three, or four unsatisfied parity checks, another count of bits may correspond to bits associated with two, three or four unsatisfied parity checks, another count of bits may correspond to bits associated with three or four unsatisfied parity checks, etc. It will be understood that the above examples are for purposes for illustration and that other configurations of the counters 160 may be implemented.

Referring to FIG. 2, a graph 200 is depicted as a simplified illustration of a bipartite graph corresponding to an ECC decoding scheme that may be implemented in the ECC decoder 152 of FIG. 1. The graph 200 includes a set of bit nodes 202 and a set of check nodes 204. Lines between the bit nodes 202 and the check nodes 204 indicate connections by parity check equations. For example, a first check node S1 has lines connecting to a second bit node b2, a fourth bit node b4, an eleventh bit node b11, and a thirteenth bit node b13. Such connections indicate that a value of the first check node S1 (e.g., a first syndrome bit) may be determined based on the exclusive-or (XOR) of the values of each of the bit nodes b2, b4, b11, and b13 (S1=b2⊕b4⊕b11⊕b13). As another example, the 10^{th} check node S10 has a value based on connections to bit nodes b6, b8, b9, and b10 (S10=b6⊕b8⊕b9⊕b10).

The graph 200 is populated based on the data 106, such as hard bit data received from the memory device 103 upon reading the data 106. As illustrated, the first check node S1 has a value of 1, and the tenth check node S10 also has a value of 1. A check node having a value of 1 signifies that the parity check equation associated with the check node is unsatisfied. A check node having a value of 0, such as the second check node S2, indicates that the parity check equation associated with a check node is satisfied (or that an even number of bit errors participate in the parity check equation).

The controller 130 (e.g., the counters 160) may determine, for each bit node 202, a count of unsatisfied parity checks associated with that bit node. For example, a first bit node b1 is associated with three parity check equations, corresponding to the second check node S2, the sixth check node S6, and the ninth check node S9. As illustrated, S2=0, S6=0 and S9=0, meaning that all check nodes associated with the first bit node b1 are satisfied. As a result, a count of unsatisfied check nodes for the first bit is 0. The second bit node b2 is associated with parity check equations corresponding to the first check node S1, the fourth check node S4, and the seventh check node S7. Each of the check nodes S1, S4, S7 has a 1 value, indicating unsatisfied parity checks. Thus, the second bit node b2 is associated with three unsatisfied parity checks.

Counts 206 corresponding to each of the bit nodes indicate the number of unsatisfied parity check equations that the bit node participates in. The counts 206 may be generated by the syndrome generator 136, by the ECC engine 138, by one or more other circuits of the controller 130, or any combination thereof. The counts 206 may be provided to the counters 160, each of which keeps track of a different value. For example, a first counter may keep track of a number of counts having a 0 value (i.e., bits that are not associated with any unsatisfied parity check equations), illustrated as a value W0 220. A second counter may keep track of a value W1 222 corresponding to a count of bits associated with one unsatisfied parity check equation (e.g., count=1), a third counter may keep track of a value W2 224 corresponding to a count of bits associated with two unsatisfied parity check equation (e.g., count=2), and a fourth counter may keep track of a value W3 226 corresponding to a count of bits associated with three unsatisfied parity check equations (e.g., count=3). In a particular implementation, the value W1 222 may correspond to the first count 162 of FIG. 1, and the value W2 224 may correspond to the second count 164. The counts 220-226 may be combined into an error metric 190, such as a generalized syndrome weight (GSW) vector.

LDPC codes can be defined using a sparse bipartite graph, such as the simplified graph 200, where the left side nodes represent the codeword bits, and the right side nodes represent parity check constraints that the codeword bits should satisfy in order to form a valid codeword.

The encoding procedure of such an LDPC code computes a set of parity bits that are concatenated to the set of information bits in order to form a codeword b=[b₁ b₂ . . . b_{N}]. The parity bits are computed as a function of the information bits such that all the parity check equations defined by the bipartite graph that represents the LDPC code are satisfied. The syndrome vector may be denoted as s=[s₁ s₂ . . . s_{M}], where sⱼ is the j'th syndrome bit which indicates whether the j'th parity check equation is satisfied (sⱼ=0) or unsatisfied (sⱼ=1). As used herein, N is a positive integer representing the number of bits in a codeword, and M is a positive integer representing the number of parity check equations for the codeword.

Hence, for a valid codeword the XOR of all the bits participating in each of the parity check equations will be equal to 0 and the syndrome vector s will be equal to 0.

When a codeword is stored into a non-volatile memory (such as NAND, BiCS, ReRAM) some errors may be introduced. When this word is later read from the memory, it will not be a valid codeword due to the presence of one or more bit errors. As a result, some of the parity check equations will not be satisfied.

The number of unsatisfied parity check equations, also known as the syndrome weight (SW), is equal to SW=Σⱼ₌₁^{M}sⱼ. The SW is correlated to the number of errors that were introduced by the memory. The expected number of unsatisfied parity check constraints monotonically increases as a function of the number of bit errors.

Hence, the SW can be used as a measure for the Bit Error Rate (BER). The expected BER as a function of SW is given by:

$$E [ BER \vert SW ] = \frac{1 - {( 1 - 2 * \frac{SW}{M} )}^{1 / {d}_{c}}}{2} , \qquad ( Eq . 1 )$$

where d_{c} is the number of bits which participate in each parity check equation (“check node degree”).

As explained above, the error metric 190 provides more information regarding bit errors as compared to the SW. The error metric 190 may include a GSW vector as follows:

GSW=[W₀W₁ . . . W_{d}_{ᵥ}], (Eq. 2)

where Wᵢ is the number of bit nodes with i unsatisfied parity check equations.

The SW can be derived from the GSW vector as follows:

$$SW = {\sum }_{j = 1}^{M} {s}_{j} = \frac{{\sum }_{i = 0}^{{d}_{v}} {W}_{i} \cdot i}{{d}_{c}} \qquad ( Eq . 3 )$$

(as Σᵢ₌₀^{d}^{ᵥ} Wᵢ·i counts every syndrome bit d_{c} times). However, the GSW vector cannot be derived from the SW value. Hence, the GSW vector contains more information than the SW value. The GSW may therefore be used for a more accurate BER estimation than can be achieved using SW.

For example, a covariance COV_{BER,GSW}(ber) between BER and GSW as a function of bit error rate (ber), a covariance COV_{GSW,GSW}(ber) between GSW and GSW as a function of ber, and a mean value μ_{GSW}(ber) of GSW as a function of ber may be computed empirically as first and second order statistics (e.g., and stored in a look-up table accessible to the controller 130) as in Equations 4-6.

COV_{BER,GSW}(ber)=E[(BER−μ_{BER})·(W−μ_{W})′|μ_{BER}=ber] Eq. 4

COV_{GSW,GSW}(ber)=E[(W−μ_{W})·(W−μ_{W})′|μ_{BER}=ber] Eq. 5

μ_{GSW}(ber)=E[W|μ_{BER}=ber] Eq. 6

COV_{BER,GSW}(ber) of Equation 4 may be a vector of size 1×(dᵥ+1), per ber value, COV_{GSW,GSW}(ber) of Equation 5 may be a matrix of size (dᵥ+1)×(dᵥ+1), per ber value, and μ_{GSW}(ber) of Equation 6 may be a vector of size (dᵥ+1)×1, per ber value.

A BER estimation (e.g., the estimated BER 180 of FIG. 1) may be generated iteratively by computing with an initial estimate and one or more updated values. For example, an initial BER estimation (that may be equivalent to conventional SW BER estimation) may be computed as:

$${ber}_{0} = \frac{1 - {( 1 - 2 * \frac{{\sum }_{i = 0}^{{d}_{v}} {W}_{i} \cdot i}{M \cdot {d}_{c}} )}^{1 / {d}_{c}}}{2} . \qquad Eq . 7$$

The initial BER estimation can be refined iteratively by taking into account the GSW information:

berⱼ=berⱼ₋₁+COV_{BER,GSW}(berⱼ₋₁)·COV_{GSW,GSW}⁻¹(berⱼ₋₁)·[W−μ_{GSW}(berⱼ₋₁)] Eq. 8

Because, after determining the initial estimate ber₀, a single iteration (i.e., ber₁) may provide a majority of the improved estimation gain, in some implementations the BER estimation may be computed as ber₁. In other implementations, the BER estimation may be computed as ber₂, ber₃, or a higher-order ber term. The GSW may reduce the estimation error of the BER by approximately 15%, on average, as compared to SW-based BER estimation. However, with some worst-case error patterns that generate high syndrome weights for a relatively low number of error bits, the SW-based BER estimation might exceed 50%, causing a controller using the SW-based BER estimation to make incorrect decisions based on the inaccurate SW-based BER estimation. In contrast, the GSW-based BER estimation may provide a far more accurate estimate of the BER.

A GSW-based BER estimation, such as the estimated BER 180, may be used in various applications. For example, the GSW-based BER estimation may be used for making improved Flash Management decisions. To illustrate, memory management algorithms may use BER estimations in order to identify various situations and take appropriate countermeasures, such as identifying that a page is to be “scrubbed” (e.g., Read Scrub), identifying that transferring data from a single-level-cell (SLC) memory portion to a multi-level-cell (MLC) memory portion was successful, or identifying that a write abort occurred, as illustrative, non-limiting examples.

A GSW-based BER estimation may be used to obtain a more accurate “health meter” for the memory 104 that can be used for different applications. For example, the health meter may be used for wear leveling and other health-based decisions.

A GSW-based BER estimation may be used for improved ECC decoding with better correction capability, latency (or throughput), and power. For example, LLR metrics used by one or more decoding modes of an ECC decoder can be adjusted as a function of the GSW based BER estimation, such as described with reference to the LLR table(s) 168. Bit flipping thresholds of a bit flipping decoding mode of the ECC decoder can be adjusted based on the GSW vector or the improved BER estimation derived from the GSW vector, such as described with reference to the flipping threshold(s) 166. The bit flipping decoder decisions may be “backtracked” based on the evolution of the GSW vector during decoding. For example, bit flipping decisions that result in improvement in the GSW vector (indicating reduced errors entropy) may be maintained, while decisions that result in degraded GSW vector (indicating increased errors entropy) may be discarded.

Decoding mode selection, early decoding termination decisions, or both, can be performed based on the GSW vector and its improved BER estimation. For example, if the estimated BER is above the correction capability of a certain decoding mode, this mode can be skipped. As another example, early termination of decoding as described with reference to the controller 130 of FIG. 1 may be at least partially based on the first count, the second count, and the count of bits of the data that are not associated with any unsatisfied parity checks, such as based on the improved BER estimation. To illustrate, early termination may be based on the GSW vector, an evolution of the GSW vector during decoding, or a combination thereof.

Bypassing decoding modes estimated to be unsuccessful, early termination of decoding, or both, improves decoder latency profile and reduces overall decoding delay of the data storage device 102.

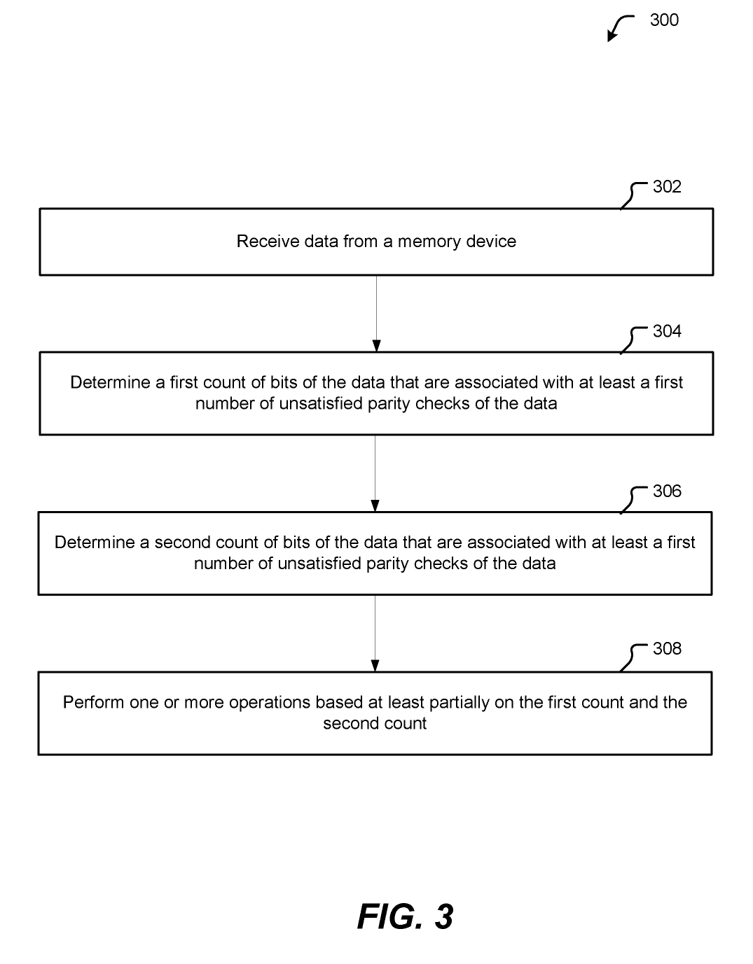

Referring to FIG. 3, a particular illustrative example of a method of operation of a device is depicted and generally designated 300. The method 300 may be performed at a data storage device, such as at the controller 130 coupled to the memory device 103 of FIG. 1.

The method 300 includes receiving data from the memory device, at 302. For example, the data 106 of FIG. 1 may be read from the memory 104 and received at the controller 130.

A first count of bits of the data that are associated with at least a first number of unsatisfied parity checks of the data is determined, at 304. For example, the first count of bits may correspond to the first count 162 of FIG. 1. As another example, the first count of bits may correspond to one of the counts W1 222, W2 224, W3 226 of FIG. 2.

A second count of bits of the data that are associated with at least a second number of unsatisfied parity checks of the data is determined, at 306. For example, the second count of bits may correspond to the second count 164 of FIG. 1. As another example, the second count of bits may correspond to another one of the counts W1 222, W2 224, W3 226 of FIG. 2.

One or more operations are performed based at least partially on the first count and the second count, at 308. The one or more operations may include verifying validity of the data based on the BER, a housekeeping operation based on the BER, or selecting an error correction code (ECC) decoding technique based on the BER, as illustrative, non-limiting examples.

The method 300 may include generating an error metric, such as the error metric 190, that has multiple elements including the first count and the second count. For example, the error metric may correspond to a generalized syndrome weight (GSW) vector that includes a count of bits of the data that are not associated with any unsatisfied parity checks, the first count of bits that are associated with one unsatisfied parity check, and the second count of bits that are associated with two unsatisfied parity checks. The error metric may further include a third count of bits that are associated with three unsatisfied parity checks.

The method 300 may include estimating a bit error rate (BER) at least partially based on the first count and the second count. For example, the estimated BER may correspond to the estimated BER 180, may be determined as described with reference to Equations 4-8, or a combination thereof.

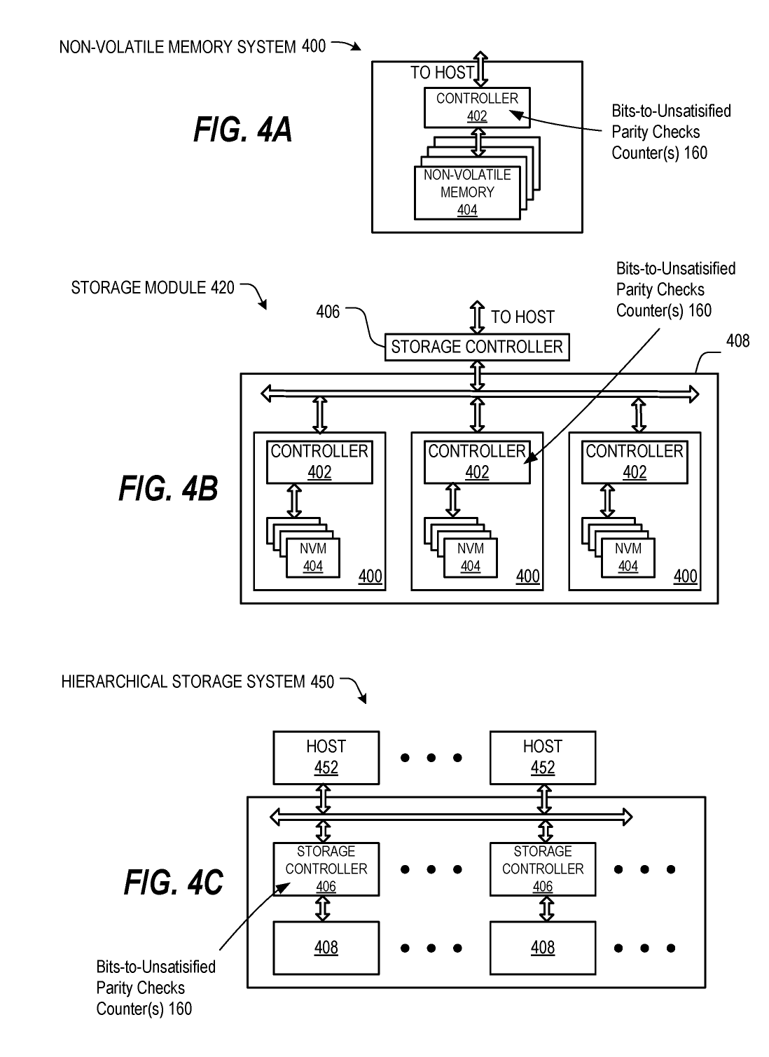

Memory systems suitable for use in implementing aspects of the disclosure are shown in FIGS. 4A-4C. FIG. 4A is a block diagram illustrating a non-volatile memory system according to an example of the subject matter described herein. Referring to FIG. 4A, a non-volatile memory system 400 includes a controller 402 and non-volatile memory (e.g., the memory device 103 of FIG. 1) that may be made up of one or more non-volatile memory die 404. As used herein, the term “memory die” refers to the collection of non-volatile memory cells, and associated circuitry for managing the physical operation of those non-volatile memory cells, that are formed on a single semiconductor substrate. The controller 402 may correspond to the controller 130 of FIG. 1. Controller 402 interfaces with a host system (e.g., the access device 170 of FIG. 1) and transmits command sequences for read, program, and erase operations to non-volatile memory die 404. The controller 402 may include the bits-to-unsatisfied parity checks counter(s) 160 of FIG. 1.

The controller 402 (which may be a flash memory controller) can take the form of processing circuitry, a microprocessor or processor, and a computer-readable medium that stores computer-readable program code (e.g., firmware) executable by the (micro)processor, logic gates, switches, an application specific integrated circuit (ASIC), a programmable logic controller, and an embedded microcontroller, for example. The controller 402 can be configured with hardware and/or firmware to perform the various functions described below and shown in the flow diagrams. Also, some of the components shown as being internal to the controller can be stored external to the controller, and other components can be used. Additionally, the phrase “operatively in communication with” could mean directly in communication with or indirectly (wired or wireless) in communication with through one or more components, which may or may not be shown or described herein.

As used herein, a flash memory controller is a device that manages data stored on flash memory and communicates with a host, such as a computer or electronic device. A flash memory controller can have various functionality in addition to the specific functionality described herein. For example, the flash memory controller can format the flash memory, map out bad flash memory cells, and allocate spare cells to be substituted for future failed cells. Some part of the spare cells can be used to hold firmware to operate the flash memory controller and implement other features. In operation, when a host is to read data from or write data to the flash memory, the host communicates with the flash memory controller. If the host provides a logical address to which data is to be read/written, the flash memory controller can convert the logical address received from the host to a physical address in the flash memory. (Alternatively, the host can provide the physical address.) The flash memory controller can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

Non-volatile memory die 404 may include any suitable non-volatile storage medium, including NAND flash memory cells and/or NOR flash memory cells. The memory cells can take the form of solid-state (e.g., flash) memory cells and can be one-time programmable, few-time programmable, or many-time programmable. The memory cells can also be single-level cells (SLC), multiple-level cells (MLC), triple-level cells (TLC), or use other memory cell level technologies, now known or later developed. Also, the memory cells can be fabricated in a two-dimensional or three-dimensional fashion.

The interface between controller 402 and non-volatile memory die 404 may be any suitable flash interface, such as Toggle Mode 200, 400, or 800. In one embodiment, non-volatile memory system 600 may be a card based system, such as a secure digital (SD) or a micro secure digital (micro-SD) card. In an alternate embodiment, memory system 400 may be part of an embedded memory system.

Although, in the example illustrated in FIG. 4A, non-volatile memory system 400 (sometimes referred to herein as a storage module) includes a single channel between controller 402 and non-volatile memory die 404, the subject matter described herein is not limited to having a single memory channel. For example, in some NAND memory system architectures (such as the ones shown in FIGS. 4B and 4C), 2, 4, 8 or more NAND channels may exist between the controller and the NAND memory device, depending on controller capabilities. In any of the embodiments described herein, more than a single channel may exist between the controller 402 and the non-volatile memory die 404, even if a single channel is shown in the drawings.

FIG. 4B illustrates a storage module 420 that includes plural non-volatile memory systems 400. As such, storage module 420 may include a storage controller 406 that interfaces with a host and with storage system 408, which includes a plurality of non-volatile memory systems 400. The interface between storage controller 406 and non-volatile memory systems 400 may be a bus interface, such as a serial advanced technology attachment (SATA) or peripheral component interface express (PCIe) interface. Storage module 420, in one embodiment, may be a solid state drive (SSD), such as found in portable computing devices, such as laptop computers, and tablet computers. Each controller 402 of FIG. 4B may include the bits-to-unsatisfied parity checks counter(s) 160. Alternatively or in addition, the storage controller 406 may include the bits-to-unsatisfied parity checks counter(s) 160.

FIG. 4C is a block diagram illustrating a hierarchical storage system. A hierarchical storage system 450 includes a plurality of storage controllers 406, each of which controls a respective storage system 408. Host systems 452 may access memories within the hierarchical storage system 450 via a bus interface. In one embodiment, the bus interface may be a Non-Volatile Memory Express (NVMe) or fiber channel over Ethernet (FCoE) interface. In one embodiment, the hierarchical storage system 450 illustrated in FIG. 4C may be a rack mountable mass storage system that is accessible by multiple host computers, such as would be found in a data center or other location where mass storage is needed. Each storage controller 406 of FIG. 4C may include the bits-to-unsatisfied parity checks counter(s) 160.

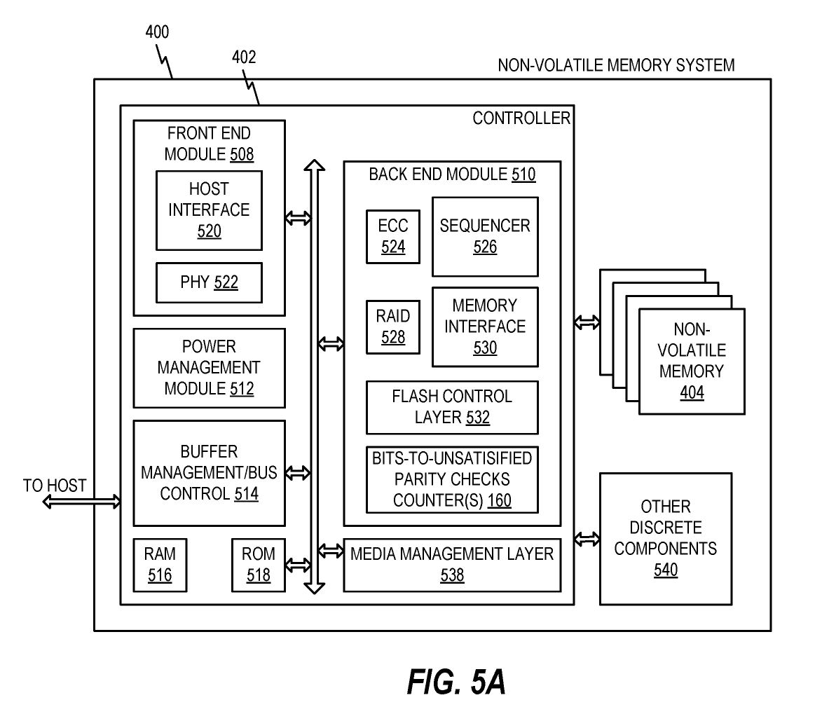

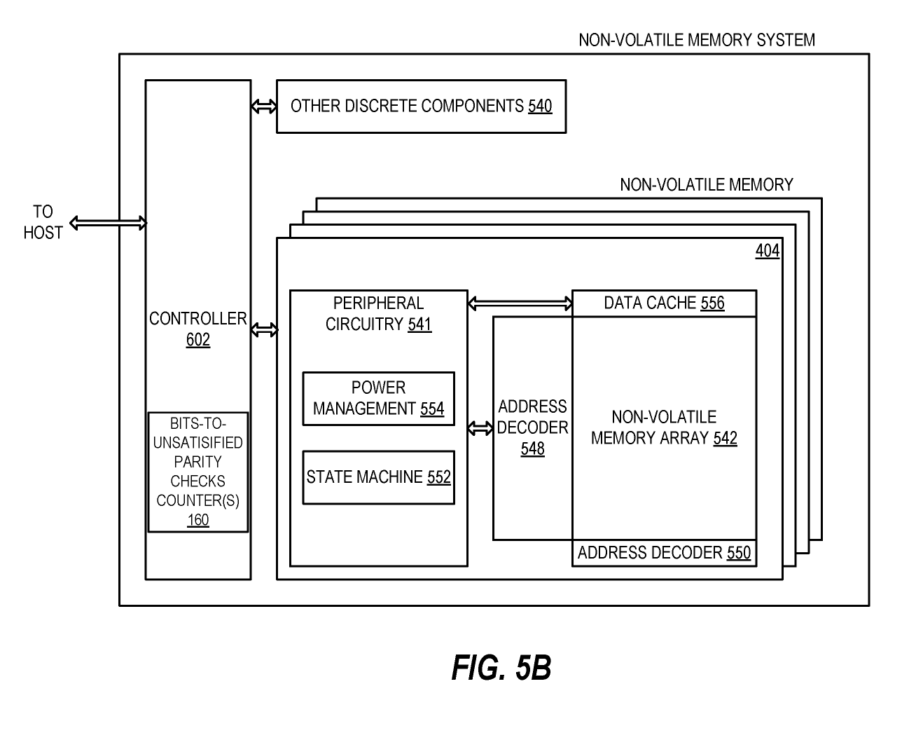

FIG. 5A is a block diagram illustrating exemplary components of the controller 402 in more detail. The controller 402 includes a front end module 508 that interfaces with a host, a back end module 510 that interfaces with the one or more non-volatile memory die 404, and various other modules that perform other functions. A module may take the form of a packaged functional hardware unit designed for use with other components, a portion of a program code (e.g., software or firmware) executable by a (micro)processor or processing circuitry that usually performs a particular function of related functions, or a self-contained hardware or software component that interfaces with a larger system, for example.

Referring again to modules of the controller 402, a buffer manager/bus controller 514 manages buffers in random access memory (RAM) 516 and controls the internal bus arbitration of the controller 402. A read only memory (ROM) 518 stores system boot code. Although illustrated in FIG. 5A as located within the controller 402, in other embodiments one or both of the RAM 516 and the ROM 518 may be located externally to the controller 402. In yet other embodiments, portions of RAM and ROM may be located both within the controller 402 and outside the controller 402.

Front end module 508 includes a host interface 520 and a physical layer interface (PHY) 522 that provide the electrical interface with the host or next level storage controller. The choice of the type of host interface 520 can depend on the type of memory being used. Examples of host interfaces 520 include, but are not limited to, SATA, SATA Express, Serial Attached Small Computer System Interface (SAS), Fibre Channel, USB, PCIe, and NVMe. The host interface 520 typically facilitates transfer for data, control signals, and timing signals.

Back end module 510 includes an error correction code (ECC) engine 524 that encodes the data received from the host, and decodes and error corrects the data read from the non-volatile memory. A command sequencer 526 generates command sequences, such as program and erase command sequences, to be transmitted to non-volatile memory die 404. A RAID (Redundant Array of Independent Drives) module 528 manages generation of RAID parity and recovery of failed data. The RAID parity may be used as an additional level of integrity protection for the data being written into the non-volatile memory die 404. In some cases, the RAID module 528 may be a part of the ECC engine 524. A memory interface 530 provides the command sequences to non-volatile memory die 404 and receives status information from non-volatile memory die 404. For example, the memory interface 530 may be a double data rate (DDR) interface, such as a Toggle Mode 200, 400, or 800 interface. A flash control layer 532 controls the overall operation of back end module 510. The back end module 510 may also include the bits-to-unsatisfied parity checks counter(s) 160.

Additional components of system 500 illustrated in FIG. 5A include a power management module 512 and a media management layer 538, which performs wear leveling of memory cells of non-volatile memory die 404. System 500 also includes other discrete components 540, such as external electrical interfaces, external RAM, resistors, capacitors, or other components that may interface with controller 402. In alternative embodiments, one or more of the physical layer interface 522, RAID module 528, media management layer 538 and buffer management/bus controller 514 are optional components that are omitted from the controller 402.

FIG. 5B is a block diagram illustrating exemplary components of non-volatile memory die 404 in more detail. Non-volatile memory die 404 includes peripheral circuitry 541 and non-volatile memory array 542. Non-volatile memory array 542 includes the non-volatile memory cells used to store data. The non-volatile memory cells may be any suitable non-volatile memory cells, including NAND flash memory cells and/or NOR flash memory cells in a two dimensional and/or three dimensional configuration. Peripheral circuitry 541 includes a state machine 552 that provides status information to controller 402, which may include the bits-to-unsatisfied parity checks counter(s) 160. The peripheral circuitry 541 may also include a power management or data latch control module 554. Non-volatile memory die 404 further includes discrete components 540, an address decoder 548, an address decoder 550, and a data cache 556 that caches data.

Although various components depicted herein are illustrated as block components and described in general terms, such components may include one or more microprocessors, state machines, or other circuits configured to enable the controller 130 to determine the first count 162 and the second count 164 of FIG. 1. For example, the syndrome generator 136, the counters 160 and associated control circuitry, or a combination thereof, may represent physical components, such as hardware controllers, state machines, logic circuits, or other structures, to generate syndrome bits and to count, for each data bit, how many “1” value syndrome bits the data bit is associated with. The syndrome generator 136, the counters 160 and associated control circuitry, or both, may be implemented using a microprocessor or microcontroller programmed to generate syndrome bits and to count, for each data bit, how many “1” value syndrome bits the data bit is associated with.

Although the controller 130 and certain other components described herein are illustrated as block components and described in general terms, such components may include one or more microprocessors, state machines, and/or other circuits configured to enable the data storage device 102 (or one or more components thereof) to perform operations described herein. Components described herein may be operationally coupled to one another using one or more nodes, one or more buses (e.g., data buses and/or control buses), one or more other structures, or a combination thereof. One or more components described herein may include one or more physical components, such as hardware controllers, state machines, logic circuits, one or more other structures, or a combination thereof, to enable the data storage device 102 to perform one or more operations described herein.

Alternatively or in addition, one or more aspects of the data storage device 102 may be implemented using a microprocessor or microcontroller programmed (e.g., by executing instructions) to perform one or more operations described herein, such as one or more operations of the methods 200-400. In a particular embodiment, the data storage device 102 includes a processor executing instructions (e.g., firmware) retrieved from the memory device 103. Alternatively or in addition, instructions that are executed by the processor may be retrieved from memory separate from the memory device 103, such as at a read-only memory (ROM) that is external to the memory device 103.

It should be appreciated that one or more operations described herein as being performed by the controller 130 may be performed at the memory device 103. As an illustrative example, in-memory ECC operations (e.g., encoding operations and/or decoding operations) may be performed at the memory device 103 alternatively or in addition to performing such operations at the controller 130.

To further illustrate, the data storage device 102 may be configured to be coupled to the access device 170 as embedded memory, such as in connection with an embedded MultiMedia Card (eMMC®) (trademark of JEDEC Solid State Technology Association, Arlington, Va.) configuration, as an illustrative example. The data storage device 102 may correspond to an eMMC device. As another example, the data storage device 102 may correspond to a memory card, such as a Secure Digital (SD®) card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). The data storage device 102 may operate in compliance with a JEDEC industry specification. For example, the data storage device 102 may operate in compliance with a JEDEC eMMC specification, a JEDEC Universal Flash Storage (UFS) specification, one or more other specifications, or a combination thereof.

The memory device 103 may include a three-dimensional (3D) memory, such as a resistive random access memory (ReRAM), a flash memory (e.g., a NAND memory, a NOR memory, a single-level cell (SLC) flash memory, a multi-level cell (MLC) flash memory, a divided bit-line NOR (DINOR) memory, an AND memory, a high capacitive coupling ratio (HiCR) device, an asymmetrical contactless transistor (ACT) device, or another flash memory), an erasable programmable read-only memory (EPROM), an electrically-erasable programmable read-only memory (EEPROM), a read-only memory (ROM), a one-time programmable memory (OTP), or a combination thereof. Alternatively or in addition, the memory device 103 may include another type of memory. In a particular embodiment, the data storage device 102 is indirectly coupled to an access device (e.g., the access device 170) via a network. For example, the data storage device 102 may be a network-attached storage (NAS) device or a component (e.g., a solid-state drive (SSD) component) of a data center storage system, an enterprise storage system, or a storage area network. The memory device 103 may include a semiconductor memory device.

Semiconductor memory devices include volatile memory devices, such as dynamic random access memory (“DRAM”) or static random access memory (“SRAM”) devices, non-volatile memory devices, such as resistive random access memory (“ReRAM”), magnetoresistive random access memory (“MRAM”), electrically erasable programmable read only memory (“EEPROM”), flash memory (which can also be considered a subset of EEPROM), ferroelectric random access memory (“FRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure. In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where they direction is substantially perpendicular and the x and z directions are substantially parallel to the major surface of the substrate). As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in they direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Alternatively, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this disclosure is not limited to the two dimensional and three dimensional exemplary structures described but cover all relevant memory structures within the spirit and scope of the disclosure as described herein and as understood by one of skill in the art. The illustrations of the embodiments described herein are intended to provide a general understanding of the various embodiments. Other embodiments may be utilized and derived from the disclosure, such that structural and logical substitutions and changes may be made without departing from the scope of the disclosure. This disclosure is intended to cover any and all subsequent adaptations or variations of various embodiments. Those of skill in the art will recognize that such modifications are within the scope of the present disclosure.

The above-disclosed subject matter is to be considered illustrative, and not restrictive, and the appended claims are intended to cover all such modifications, enhancements, and other embodiments, that fall within the scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A device comprising:
a memory device; and
a controller coupled to the memory device, the controller configured to determine, based on data read from the memory device, a first count of bits of the data that are associated with at least a first number of unsatisfied parity checks of the data and a second count of bits of the data that are associated with at least a second number of unsatisfied parity checks of the data, the controller further configured to perform one or more operations based at least partially on the first count and the second count.

2. The device of claim 1, wherein the controller is configured to generate an error metric that includes the first count and the second count.

3. The device of claim 2, wherein the error metric corresponds to a generalized syndrome weight vector that includes a count of bits of the data that are not associated with any unsatisfied parity checks, the first count of bits, and the second count of bits.

4. The device of claim 3, wherein the first number is one, wherein the second number is two, and wherein the error metric further includes a third count of bits that are associated with three unsatisfied parity checks.

5. The device of claim 1, wherein the controller is configured to estimate a bit error rate (BER) at least partially based on the first count and the second count.

6. The device of claim 5, wherein the one or more operations includes verifying validity of the data based on the BER.

7. The device of claim 5, wherein the one or more operations includes a housekeeping operation based on the BER.

8. The device of claim 5, wherein the one or more operations includes selecting an error correction code (ECC) decoding mode based on the BER.

9. A data storage device comprising:
a non-volatile memory; and
a controller coupled to the non-volatile memory, the controller configured to receive data from the non-volatile memory and to initialize an error correction code (ECC) decoder at least partially based on a first count of bits of the data that are associated with at least a first number of unsatisfied parity checks of the data, a second count of bits of the data that are associated with at least a second number of unsatisfied parity checks of the data, and a count of bits of the data that are not associated with any unsatisfied parity checks of the data.

10. The data storage device of claim 9, wherein the controller is configured to determine log likelihood ratio (LLR) data of the ECC decoder at least partially based on the first count, the second count, and the count of bits of the data that are not associated with any unsatisfied parity checks.

11. The data storage device of claim 9, wherein the controller is configured to determine a bit flipping threshold of the ECC decoder at least partially based on the first count, the second count, and the count of bits of the data that are not associated with any unsatisfied parity checks.

12. The data storage device of claim 9, wherein the controller is configured to select a decoding mode of the ECC decoder at least partially based on the first count, the second count, and the count of bits of the data that are not associated with any unsatisfied parity checks.

13. The data storage device of claim 9, wherein the controller is configured to perform a particular number of ECC decoding iterations, and wherein the controller is configured to terminate, at least partially based on the first count, the second count, and the count of bits of the data that are not associated with any unsatisfied parity checks, an ECC decoding operation prior to completing the particular number of ECC decoding iterations.

14. The data storage device of claim 9, wherein the controller is configured to determine a change of the first count, the second count, and the count of bits of the data that are not associated with any unsatisfied parity checks, the change resulting from one or more bit-flipping decisions, and to selectively discard the one or more bit-flipping decisions based on the change.

15. A method comprising:
at a controller coupled to a memory device, performing:
receiving data from the memory device;
determining a first count of bits of the data that are associated with at least a first number of unsatisfied parity checks of the data;
determining a second count of bits of the data that are associated with at least a second number of unsatisfied parity checks of the data; and
performing one or more operations based at least partially on the first count and the second count.

16. The method of claim 15, further comprising generating an error metric that includes the first count and the second count.

17. The method of claim 16, wherein the error metric corresponds to a generalized syndrome weight vector that includes a count of bits of the data that are not associated with any unsatisfied parity checks, the first count, and the second count.

18. The method of claim 17, wherein the first number is one, wherein the second number is two, and wherein the error metric further includes a third count of bits that are associated with three unsatisfied parity checks.

19. The method of claim 15, further comprising estimating a bit error rate (BER) at least partially based on the first count and the second count.

20. The method of claim 19, wherein the one or more operations includes verifying validity of the data based on the BER.

21. The method of claim 19, wherein the one or more operations includes a housekeeping operation based on the BER.

22. The method of claim 19, wherein the one or more operations includes selecting an error correction code (ECC) decoding technique based on the BER.
